(19) United States
(12) Patent Application Publication
(10) Pub. No.: US 2026/0075841 A1
(43) Pub. Date: Mar. 12, 2026

(54) MEMORY DEVICE

(71) Applicant: KIOXIA CORPORATION, Tokyo (JP)

(72) Inventors: Katsuyoshi KOMATSU, Yokkaichi Mie (JP); Hiroki KAWAI, Inazawa Aichi (JP); Tadaomi DAIBOU, Yokkaichi Mie (JP); Takayuki TSUKAGOSHI, Inagi Tokyo (JP)

(73) Assignee: KIOXIA CORPORATION, Tokyo (JP)

(21) Appl. No.: 19/081,064

(22) Filed: Mar. 17, 2025

(30) Foreign Application Priority Data
Sep. 12, 2024 (JP) 2024-157945

(51) Int. Cl. H10B 63/00; G11C 13/00; H10B 61/00; H10N 50/10; H10N 70/00

(52) U.S. Cl. CPC H10B 63/80; H10B 61/10; H10B 63/20; H10N 50/10; H10N 70/826; H10N 70/8822; H10N 70/8825; H10N 70/8828; H10N 70/883; H10N 70/8833; G11C 13/004; G11C 13/0069

(57) ABSTRACT

A memory device of embodiments includes a memory cell in which a first conductive layer, a switching layer, a third conductive layer, a variable resistance layer, and a second conductive layer are stacked in this order. The switching layer contains two-dimensional crystals. The first conductive layer or the second conductive layer contains two-dimensional crystals. When the memory cell is in a low resistance state, a nonlinear current-voltage characteristic that a current increases at a specific first threshold voltage appears as the absolute value of a voltage increases, and a current-voltage characteristic that the current decreases at a voltage having an absolute value smaller than that of the first threshold voltage appears as the absolute value of the voltage decreases from a voltage exceeding the first threshold voltage.

### CROSS-REFERENCE TO RELATED APPLICATION

This application is based upon and claims the benefit of priority from Japanese Patent Application No. 2024-157945, filed on Sep. 12, 2024, the entire contents of which are incorporated herein by reference.

### FIELD

Embodiments described herein relate generally to a memory device.

### BACKGROUND

As a large-capacity nonvolatile memory device, there is a cross-point type two-terminal memory device. In the cross-point type two-terminal memory device, scaling-down and high integration of memory cells are easy.

Each memory cell of the cross-point type two-terminal memory device has, for example, a variable resistance element and a switching element. Since the memory cell has a switching element, the current flowing through memory cells other than the selected memory cell is suppressed.

The switching element is required to have excellent characteristics, such as low leakage current, high on-current, and high reliability.

### BRIEF DESCRIPTION OF THE DRAWINGS

FIG. 1 is a block diagram of a memory device according to a first embodiment;

FIG. 2 is a schematic cross-sectional view of a memory cell in the memory device according to the first embodiment;

FIG. 3 is an explanatory diagram of the current-voltage characteristic of the memory device according to the first embodiment;

FIG. 4 is a schematic cross-sectional view of a memory cell in a memory device according to a first modification example of the first embodiment;

FIG. 5 is a schematic cross-sectional view of a memory cell of a memory device according to a second modification example of the first embodiment;

FIG. 6 is a schematic cross-sectional view of a memory cell in a memory device according to a second embodiment;

FIG. 7 is an explanatory diagram of the current-voltage characteristic of the memory device according to the second embodiment;

FIG. 8 is a schematic cross-sectional view of a memory cell in a memory device according to a first modification example of the second embodiment;

FIG. 9 is a schematic cross-sectional view of a memory cell in a memory device according to a second modification example of the second embodiment;

FIG. 10 is a schematic cross-sectional view of a memory cell in a memory device according to a third embodiment;

FIG. 11 is a schematic cross-sectional view of a memory cell in a memory device according to a fourth embodiment;

FIG. 12 is an explanatory diagram of the current-voltage characteristic of the memory device according to the fourth embodiment; and

FIG. 13 is a schematic cross-sectional view of a memory cell in a memory device according to a modification example of the fourth embodiment.

### DETAILED DESCRIPTION

A memory device of embodiments includes a memory cell including a first conductive layer, a second conductive layer, a third conductive layer provided between the first conductive layer and the second conductive layer, a switching layer provided between the first conductive layer and the third conductive layer, and a variable resistance layer provided between the third conductive layer and the second conductive layer, the memory cell having an electrical resistance changing with application of a predetermined voltage and having a low resistance state and a high resistance state having a higher electrical resistance than in the low resistance state. The switching layer contains at least one first compound selected from a group consisting of molybdenum disulfide, molybdenum diselenide, molybdenum ditelluride, tungsten disulfide, tungsten diselenide, indium selenide, gallium sulfide, gallium selenide, gallium telluride, germanium sulfide, germanium selenide, germanium telluride, silicon sulfide, silicon selenide, silicon telluride, tin sulfide, tin selenide, tin telluride, rhenium disulfide, rhenium diselenide, and rhenium ditelluride. At least one of the first conductive layer and the third conductive layer contains at least one second compound selected from a group consisting of tungsten ditelluride, titanium disulfide, titanium diselenide, tantalum disulfide, tantalum diselenide, niobium disulfide, niobium diselenide, hafnium disulfide, and hafnium diselenide, graphene, or graphite.

When the memory cell is in the low resistance state, if a voltage is applied between the first conductive layer and the second conductive layer, a nonlinear current-voltage characteristic that a current increases at a first threshold voltage appears as an absolute value of the voltage increases, and a current-voltage characteristic that a current decreases at a first voltage having an absolute value smaller than that of the first threshold voltage appears as the absolute value of the voltage decreases from a voltage exceeding the first threshold voltage.

Hereinafter, embodiments will be described with reference to the diagrams. In addition, in the following description, the same or similar members and the like are denoted by the same reference numerals, and the description of the members and the like once described will be omitted as appropriate.

The qualitative analysis and quantitative analysis of the chemical composition forming the memory device in this specification can be performed by, for example, Rutherford backscattering spectroscopy (RBS), secondary ion mass spectroscopy (SIMS), energy dispersive X-ray spectroscopy (EDX), or electron energy loss spectroscopy (EELS). In addition, when measuring the thickness of each member forming the memory device, a distance between members, and the like, for example, a transmission electron microscope (TEM) can be used. In addition, for example, a scanning transmission electron microscope (STEM), X-ray photoelectron spectroscopy (XPS), X-ray absorption fine structure (XAFS), Raman spectroscopy (Raman), or EELS can be used to identify the constituent materials of each member forming the memory device and to measure the presence ratio, bonding state, local structure (atomic distance, coordination number), and chemical state thereof. In addition, for example, EELS can be used to measure the band gap of each member forming the memory device.

In this specification, “two-dimensional crystal” refers to a structure in which atoms or molecules are periodically arranged in a two-dimensional plane. Single-layer “two-dimensional crystals” are bonded together by von der Waals forces and stacked together to form a three-dimensional structure.

### First Embodiment

A memory device according to a first embodiment includes a memory cell including a first conductive layer, a second conductive layer, a third conductive layer provided between the first conductive layer and the second conductive layer, a switching layer provided between the first conductive layer and the third conductive layer, and a variable resistance layer provided between the third conductive layer and the second conductive layer, the memory cell having an electrical resistance changing with application of a predetermined voltage and having a low resistance state and a high resistance state having a higher electrical resistance than in the low resistance state. The switching layer contains at least one first compound selected from a group consisting of molybdenum disulfide, molybdenum diselenide, molybdenum ditelluride, tungsten disulfide, tungsten diselenide, indium selenide, gallium sulfide, gallium selenide, gallium telluride, germanium sulfide, germanium selenide, germanium telluride, silicon sulfide, silicon selenide, silicon telluride, tin sulfide, tin selenide, tin telluride, rhenium disulfide, rhenium diselenide, and rhenium ditelluride. At least one of the first conductive layer and the third conductive layer contains at least one second compound selected from a group consisting of tungsten ditelluride, titanium disulfide, titanium diselenide, tantalum disulfide, tantalum diselenide, niobium disulfide, niobium diselenide, hafnium disulfide, and hafnium diselenide, graphene, or graphite. When the memory cell is in the low resistance state, if a voltage is applied between the first conductive layer and the second conductive layer, a nonlinear current-voltage characteristic that a current increases at a first threshold voltage appears as an absolute value of the voltage increases, and a current-voltage characteristic that a current decreases at a first voltage having an absolute value smaller than that of the first threshold voltage appears as the absolute value of the voltage decreases from a voltage exceeding the first threshold voltage.

In addition, the memory device according to the first embodiment further includes a plurality of first wirings and a plurality of second wirings crossing the plurality of first wirings. Then, the memory cell is provided in a region where one of the plurality of first wirings and one of the plurality of second wirings cross each other.

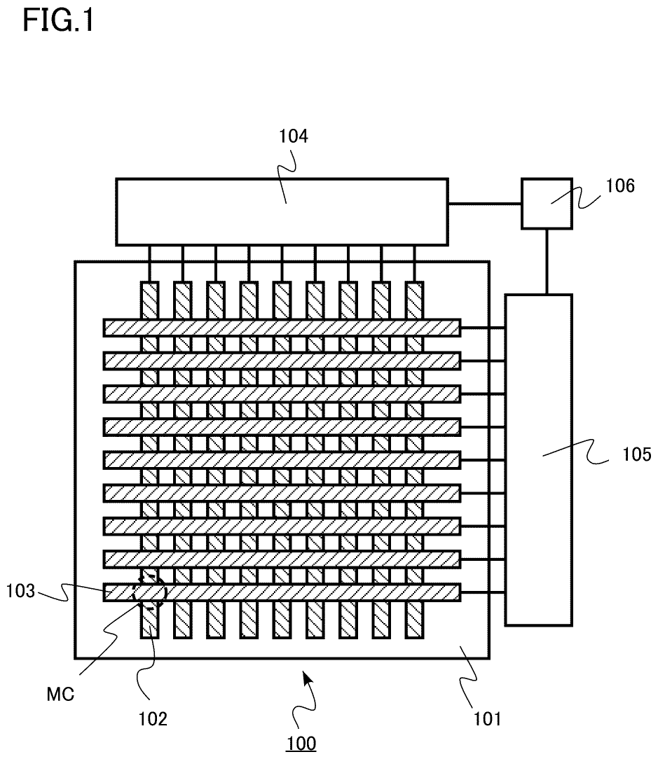

FIG. 1 is a block diagram of the memory device according to the first embodiment.

A memory cell array 100 in the memory device according to the first embodiment includes, for example, a plurality of word lines 102 and a plurality of bit lines 103 crossing the word lines 102 on a semiconductor substrate 101 with an insulating layer interposed therebetween. The bit lines 103 are provided in a layer above the word lines 102, for example. In addition, a first control circuit 104, a second control circuit 105, and a sense circuit 106 are provided as peripheral circuits around the memory cell array 100.

The word line 102 is an example of the first wiring. In addition, the bit line 103 is an example of the second wiring.

A plurality of memory cells MC are provided in regions where the word lines 102 and the bit lines 103 cross each other. The memory device according to the first embodiment is a two-terminal magnetoresistive memory having a cross-point structure.

Each of the plurality of word lines 102 is connected to the first control circuit 104. In addition, each of the plurality of bit lines 103 is connected to the second control circuit 105. The sense circuit 106 is connected to the first control circuit 104 and the second control circuit 105.

The first control circuit 104 and the second control circuit 105 have functions of selecting a desired memory cell MC, writing data to the memory cell MC, reading data from the memory cell MC, and deleting data from the memory cell MC, for example. When reading data, the data in the memory cell MC is read as the amount of current flowing between the word line 102 and the bit line 103 or as an electric potential change of the bit line 103. The sense circuit 106 has a function of determining the amount of current or the electric potential change to determine the polarity of the data. For example, “0” and “1” of data are determined.

The first control circuit 104, the second control circuit 105, and the sense circuit 106 are electronic circuits using semiconductor devices formed on the semiconductor substrate 101, for example.

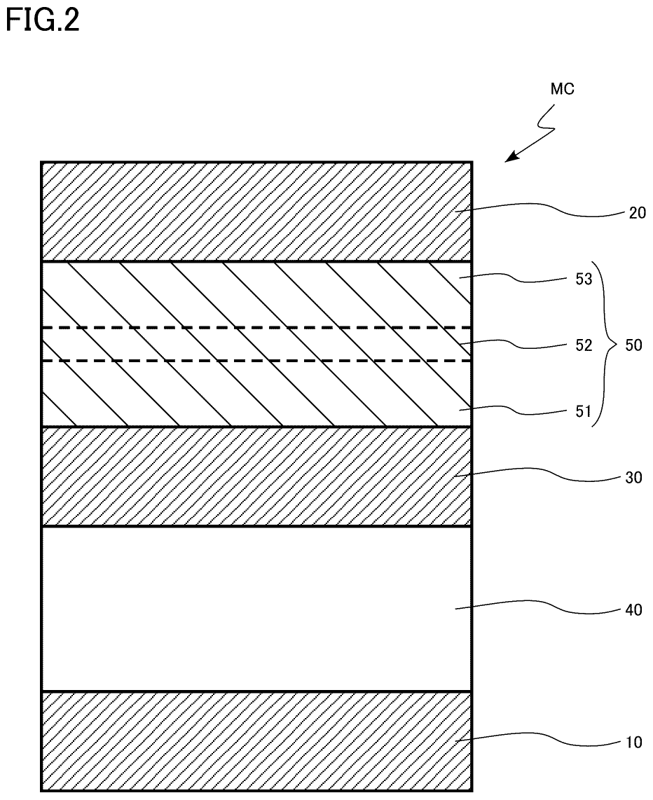

FIG. 2 is a schematic cross-sectional view of a memory cell in the memory device according to the first embodiment. FIG. 2 shows a cross section of one memory cell MC indicated by, for example, a dotted circle in the memory cell array 100 of FIG. 1.

As shown in FIG. 2, the memory cell MC includes a lower electrode 10, an upper electrode 20, an intermediate electrode 30, a switching layer 40, and a variable resistance layer 50. The variable resistance layer 50 includes a fixed layer 51, a tunnel layer 52, and a free layer 53.

The lower electrode 10 is an example of the first conductive layer. The upper electrode 20 is an example of the second conductive layer. The intermediate electrode 30 is an example of the third conductive layer.

The lower electrode 10, the switching layer 40, and the intermediate electrode 30 form a switching element of the memory cell MC. The intermediate electrode 30, the variable resistance layer 50, and the upper electrode 20 form a variable resistance element of the memory cell MC.

The memory cell MC has an electrical resistance that changes with the application of a predetermined voltage.

Since the electrical resistance changes, the memory cell MC can have a low resistance state and a high resistance state. The electrical resistance in the high resistance state is higher than the electrical resistance in the low resistance state.

The switching layer 40 is provided between the lower electrode 10 and the intermediate electrode 30. The thickness of the switching layer 40 in a direction from the lower electrode 10 to the upper electrode 20 is, for example, equal to or more than 0.5 nm and equal to or less than 50 nm.

The switching layer 40 has a nonlinear current-voltage characteristic that a current increases abruptly at a specific threshold voltage. The switching layer 40 has a function of suppressing a leakage current flowing through unselected cells. The switching layer 40 functions as a so-called selector in the memory cell MC.

The switching layer 40 contains at least one first compound selected from a group consisting of molybdenum disulfide, molybdenum diselenide, molybdenum ditelluride, tungsten disulfide, tungsten diselenide, indium selenide, gallium sulfide, gallium selenide, gallium telluride, germanium sulfide, germanium selenide, germanium telluride, silicon sulfide, silicon selenide, silicon telluride, tin sulfide, tin selenide, tin telluride, rhenium disulfide, rhenium diselenide, and rhenium ditelluride.

Molybdenum disulfide can be written as MoS2. Molybdenum diselenide can be written as MoSe2. Molybdenum ditelluride can be written as MoTe2. Tungsten disulfide can be written as WS2. Tungsten diselenide can be written as WSe2. Indium selenide can be written as InSe. Gallium sulfide can be written as GaS. Gallium selenide can be written as GaSe. Gallium telluride can be written as GaTe. Germanium sulfide can be written as GeS. Germanium selenide can be written as GeSe. Germanium telluride can be written as GeTe. Silicon sulfide can be written as SiS. Silicon selenide can be written as SiSe. Silicon telluride can be written as SiTe. Tin sulfide can be written as SnS. Tin selenide can be written as SnSe. Tin telluride can be written as SnTe. Rhenium disulfide can be written as ReS2. Rhenium diselenide can be written as ReSe2. Rhenium ditelluride can be written as ReT2.

The switching layer 40 contains two-dimensional crystals. For example, the switching layer 40 contains single-layer two-dimensional crystals or multi-layer two-dimensional crystals.

The switching layer 40 contains crystals of a space group P63/mmc, crystals of a space group Pnma62, or crystals of a space group P-1. Crystals of the space group P63/mmc, crystals of the space group Pnma62, and crystals of the space group P-1 are two-dimensional crystals.

The first compound contained in the switching layer 40 is a two-dimensional crystal. The space group of molybdenum disulfide, molybdenum diselenide, molybdenum ditelluride, tungsten disulfide, tungsten diselenide, indium selenide, gallium sulfide, gallium selenide, and gallium telluride is P63/mmc. The space group of germanium sulfide, germanium selenide, germanium telluride, silicon sulfide, silicon selenide, silicon telluride, tin sulfide, tin selenide, and tin telluride is Pnma62. The space group of rhenium disulfide, rhenium diselenide, and rhenium ditelluride is P-1.

The first compound is a chalcogenide. The first compound is a semiconductor. The first compound has a characteristic that its band gap changes with the application of a voltage. The first compound has a characteristic that, as a voltage is applied, its band gap decreases and its electrical resistance decreases.

The lower electrode 10 is connected to the word line 102. The lower electrode 10 may be a part of the word line 102. The lower electrode 10 is in contact with, for example, the switching layer 40.

The upper electrode 20 is connected to the bit line 103. The upper electrode 20 may be a part of the bit line 103. The upper electrode 20 is in contact with, for example, the variable resistance layer 50.

The intermediate electrode 30 is provided between the lower electrode 10 and the upper electrode 20. The intermediate electrode 30 is in contact with, for example, the switching layer 40 and the variable resistance layer 50.

At least one of the lower electrode 10 and the intermediate electrode 30 contains at least one second compound selected from a group consisting of tungsten ditelluride, titanium disulfide, titanium diselenide, tantalum disulfide, tantalum diselenide, niobium disulfide, niobium diselenide, hafnium disulfide, and hafnium diselenide, graphene, or graphite.

The lower electrode 10 contains, for example, at least one second compound selected from a group consisting of tungsten ditelluride, titanium disulfide, titanium diselenide, tantalum disulfide, tantalum diselenide, niobium disulfide, niobium diselenide, hafnium disulfide, and hafnium diselenide, graphene, or graphite.

Tungsten ditelluride can be written as WTe₂. Titanium disulfide can be written as TiS₂. Titanium diselenide can be written as TiSe₂. Tantalum disulfide can be written as TaS₂. Tantalum diselenide can be written as TaSe₂. Niobium disulfide can be written as NbS₂. Niobium diselenide can be written as NbSe₂. Hafnium disulfide can be written as HfS₂. Hafnium diselenide can be written as HfSe_{2.}

The lower electrode 10 contains, for example, two-dimensional crystals. For example, the lower electrode 10 contains single-layer two-dimensional crystals or multilayer two-dimensional crystals. The surface of the lower electrode 10 on the switching layer 40 side is, for example, a two-dimensional crystal.

The second compound, graphene, and graphite contained in the lower electrode 10 are two-dimensional crystals.

The intermediate electrode 30 contains, for example, at least one second compound selected from a group consisting of tungsten ditelluride, titanium disulfide, titanium diselenide, tantalum disulfide, tantalum diselenide, niobium disulfide, niobium diselenide, hafnium disulfide, and hafnium diselenide, graphene, or graphite.

The intermediate electrode 30 contains, for example, two-dimensional crystals. For example, the intermediate electrode 30 contains single-layer two-dimensional crystals or multi-layer two-dimensional crystals. The surface of the intermediate electrode 30 on the switching layer 40 side is, for example, a two-dimensional crystal.

The second compound, graphene, and graphite contained in the intermediate electrode 30 are two-dimensional crystals.

The upper electrode 20 is, for example, a metal. The upper electrode 20 contains, for example, at least one material selected from a group consisting of graphite, carbon nitride, tungsten, tungsten carbide, and tungsten nitride.

In addition, only one of the lower electrode 10 and the intermediate electrode 30 may contain the second compound, graphene, or graphite.

When the intermediate electrode 30 contains the second compound, graphene, or graphite, the lower electrode 10 contains, for example, at least one material selected from a group consisting of graphite, carbon nitride, tungsten, tungsten carbide, and tungsten nitride.

When the lower electrode 10 contains the second compound, graphene, or graphite, the intermediate electrode 30 contains, for example, at least one material selected from a group consisting of graphite, carbon nitride, tungsten, tungsten carbide, and tungsten nitride.

When forming the switching layer 40 of a two-dimensional crystal on the lower electrode 10 of a two-dimensional crystal, for example, a dry transfer method that suppresses the formation of bubbles at the interface between the lower electrode 10 and the switching layer 40 is used. In addition, when forming the intermediate electrode 30 of a two-dimensional crystal on the switching layer 40 of a two-dimensional crystal, for example, a dry transfer method that suppresses the formation of bubbles at the interface between the switching layer 40 and the intermediate electrode 30 is used. By using the dry transfer method that suppresses the formation of bubbles at the interface, the interface between the lower electrode 10 and the switching layer 40 and the interface between the switching layer 40 and the intermediate electrode 30 can be cleaned.

The variable resistance layer 50 is provided between the intermediate electrode 30 and the upper electrode 20. The variable resistance layer 50 includes the fixed layer 51, the tunnel layer 52, and the free layer 53. The variable resistance layer 50 includes a magnetic tunnel junction formed by the fixed layer 51, the tunnel layer 52, and the free layer 53.

The variable resistance layer 50 has a function of storing data by resistance change. The variable resistance layer 50 has, for example, a characteristic that its electrical resistance changes with the application of a predetermined voltage.

The fixed layer 51 is a ferromagnetic material. In the fixed layer 51, its magnetization direction does not change with respect to a predetermined write voltage, but is fixed in a specific direction.

The tunnel layer 52 is an insulator. Electrons pass through the tunnel layer 52 by the tunnel effect.

The free layer 53 is a ferromagnetic material. In the free layer 53, its magnetization direction changes with respect to a predetermined write voltage. The magnetization direction of the free layer 53 can be parallel to the magnetization direction of the fixed layer 51 or can be antiparallel to the magnetization direction of the fixed layer 51. For example, by applying a voltage between the intermediate electrode 30 and the upper electrode 20 so that a current flow between the intermediate electrode 30 and the upper electrode 20, the magnetization direction of the free layer 53 can be changed.

By changing the magnetization direction of the free layer 53, the electrical resistance of the variable resistance layer 50 changes. When the magnetization direction of the free layer 53 is antiparallel to the magnetization direction of the fixed layer 51, a high resistance state in which a current hardly flows is realized. On the other hand, when the magnetization direction of the free layer 53 is parallel to the magnetization direction of the fixed layer 51, a low resistance state in which a current flows easily is realized. In addition, the arrangement of the fixed layer 51 and the free layer 53 may be reversed. That is, the intermediate electrode 30, the free layer 53, the tunnel layer 52, the fixed layer 51, and the upper electrode 20 may be stacked in this order.

When the variable resistance layer 50 is in a low resistance state, the memory cell MC is in a low resistance state. In addition, when the variable resistance layer 50 is in a high resistance state, the memory cell MC is in a high resistance state.

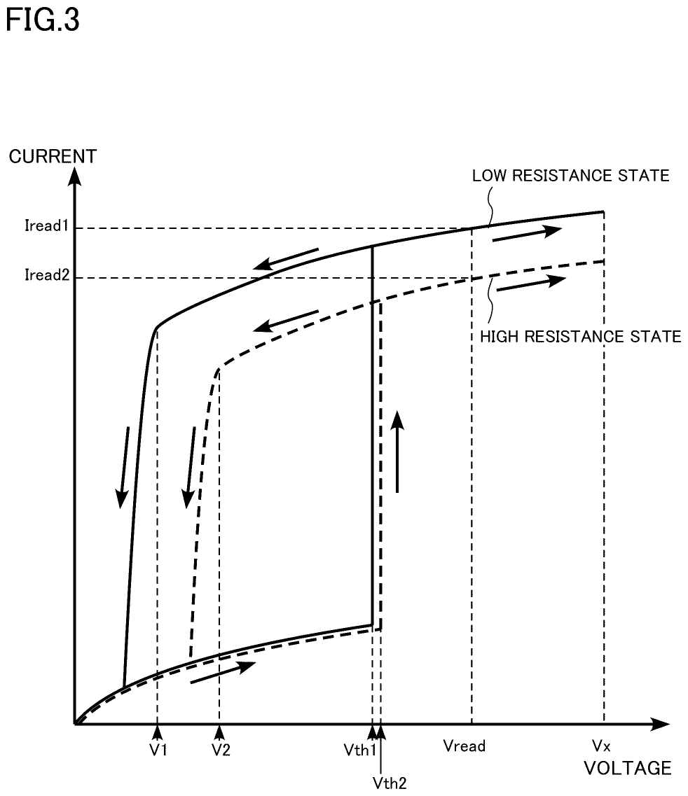

FIG. 3 is an explanatory diagram of the current-voltage characteristic of the memory device according to the first embodiment. The horizontal axis indicates a voltage applied between the lower electrode 10 and the upper electrode 20 of the memory cell MC, and the vertical axis indicates a current flowing between the lower electrode 10 and the upper electrode 20 of the memory cell MC. The vertical axis is, for example, a log scale.

Hereinafter, a case where a voltage that is positive with respect to the lower electrode 10 is applied to the upper electrode 20 will be described as an example. A voltage that is negative with respect to the lower electrode 10 may be applied to the upper electrode 20. When a voltage that is negative with respect to the lower electrode 10 is applied to the upper electrode 20, the arrow direction on the horizontal axis in FIG. 3 indicates a direction in which the negative value increases. In both the case where a voltage that is positive with respect to the lower electrode 10 is applied to the upper electrode 20 and the case where a voltage that is negative with respect to the lower electrode 10 is applied to the upper electrode 20, the arrow direction in FIG. 3 indicates a direction in which the absolute value of the applied voltage increases.

In FIG. 3, the solid line shows a current-voltage characteristic when the memory cell MC is in a low resistance state. In addition, in FIG. 3, the dotted line shows a current-voltage characteristic when the memory cell MC is in a high resistance state. In FIG. 3, the arrows along the current-voltage characteristics indicate the sweep direction of the voltage.

First, the current-voltage characteristic when the memory cell MC is in a low resistance state will be described. As the applied voltage increases, a nonlinear current-voltage characteristic that the current increases at a first threshold voltage (Vth1 in FIG. 3) appears.

Thereafter, when the voltage is reduced from a voltage (Vx in FIG. 3) exceeding the first threshold voltage Vth1, the current decreases at a first voltage (V1 in FIG. 3) lower than the first threshold voltage. In other words, when the memory cell MC is in a low resistance state, the current-voltage characteristic of the memory cell MC shows hysteresis. For example, the first voltage V1 is equal to or more than 0.1 times and equal to or less than 0.9 times the first threshold voltage Vth1.

Next, the current-voltage characteristic when the memory cell MC is in a high resistance state will be described. As the applied voltage increases, a nonlinear current-voltage characteristic that the current increases at a specific second threshold voltage (Vth2 in FIG. 3) appears. Thereafter, when the voltage is reduced from the voltage (Vx in FIG. 3) exceeding the second threshold voltage Vth2, the current decreases at a second voltage (V2 in FIG. 3) lower than the second threshold voltage. In other words, when the memory cell MC is in a high resistance state, the current-voltage characteristic of the memory cell MC shows hysteresis. For example, the second voltage V2 is equal to or more than 0.1 times and equal to or less than 0.9 times the second threshold voltage Vth2.

The second threshold voltage Vth2 and the first threshold voltage Vth1 are, for example, approximately equal in magnitude. In addition, the second voltage V2 is, for example, larger than the first voltage V1.

For example, the high resistance state of the variable resistance layer 50 is defined as data “1”, and the low resistance state of the variable resistance layer 50 is defined as data “0”. Since the memory cell MC can maintain different resistance states, it is possible to store 1-bit data of “0” and “1”.

When reading data from the memory cell MC, for example, a voltage higher than the first threshold voltage Vth1 and the second threshold voltage Vth2 is set as a read voltage Vread. When the memory cell MC is in a low resistance state, a first read current Iread1 flows. In addition, when the memory cell MC is in a high resistance state, a second read current Iread2 flows. The first read current Iread1 is larger than the second read current Iread2. For example, by detecting the magnitude of the read current when the read voltage Vread is applied to the memory cell MC, it is possible to determine the data written in the memory cell MC.

Next, the function and effect of the memory device according to the first embodiment will be described.

In the memory device according to the first embodiment, as shown in FIG. 1, a plurality of memory cells MC are provided in a region where the word line 102 and the bit line 103 cross each other. For example, when one memory cell MC of the plurality of memory cells MC is selected for a read operation, it is necessary to suppress a leakage current flowing through unselected cells other than the selected cell. This is because, if the leakage current flowing through the unselected cells increases, for example, data read error occurs or the power consumption of the memory device increases.

In the memory device according to the first embodiment, as shown in FIG. 3, when the memory cell MC is in a low resistance state, the memory cell MC has a nonlinear current-voltage characteristic that the current increases abruptly at the first threshold voltage. In addition, when the memory cell MC is in a high resistance state, the memory cell MC has a nonlinear current-voltage characteristic that the current increases abruptly at the second threshold voltage. Therefore, in the memory device according to the first embodiment, it is possible to suppress a leakage current flowing through the unselected cell, which has a voltage applied between electrodes that is lower than that in the selected cell. As a result, it is possible to realize a memory device with stable read operations and reduced power consumption, for example.

In addition, the reason why the memory cell MC has a nonlinear current-voltage characteristic that the current increases abruptly at a specific threshold voltage is that the switching layer 40 has a nonlinear current-voltage characteristic that the current increases abruptly at the specific threshold voltage.

The switching layer 40 of the memory device according to the first embodiment contains two-dimensional crystals having a stable and flat two-dimensional structure. Since the switching layer 40 contains two-dimensional crystals having a stable and flat two-dimensional structure, it is possible to realize the switching layer 40 with small variations in characteristics and excellent endurance characteristics. Therefore, it is possible to realize a highly reliable memory device with small variations in characteristics.

In addition, when the memory cell MC of the memory device according to the first embodiment is in a low resistance state, the current-voltage characteristic shows hysteresis as shown in FIG. 3. By providing the current-voltage characteristic with hysteresis, the current flowing through the memory cell MC after the voltage applied to the memory cell MC exceeds the first threshold voltage Vth1 increases compared to a case without hysteresis.

In addition, the reason why the current-voltage characteristic of the memory cell MC in a low resistance state has hysteresis is that the current-voltage characteristic of the switching layer 40 has hysteresis. By providing the current-voltage characteristic of the switching layer 40 with hysteresis, the current after exceeding the threshold voltage of the switching layer 40 increases to improve the ON/OFF ratio of the switching layer 40. Since the ON/OFF ratio of the switching layer 40 is improved, it is possible to realize a memory device with stable read operations and reduced power consumption, for example.

As described above, the two-dimensional crystalline switching layer 40 has a nonlinear current-voltage characteristic that the current increases abruptly at a specific threshold voltage, and the current-voltage characteristic has hysteresis. This is believed to be due to the fact that the first compound whose band gap decreases with the application of a voltage is selected as the two-dimensional crystal of the switching layer 40, that the electrode in contact with the switching layer 40 is formed of two-dimensional crystal, and that the interface between two-dimensional crystals between the switching layer 40 and the electrode is a clean interface. The clean interface between the switching layer 40 and the electrode is believed to be due to the use of a dry transfer method that suppresses the formation of bubbles at the interface when forming the switching layer 40 and the electrode.

According to the first embodiment, it is possible to realize a memory device with stable operating characteristics, reduced power consumption, and improved reliability.

From the viewpoint of realizing the scaling-down of a memory device, the thickness of the switching layer 40 in a direction from the lower electrode 10 to the upper electrode 20 is preferably equal to or less than 50 nm, more preferably equal to or less than 20 nm, and even more preferably equal to or less than 10 nm.

In addition, from the viewpoint of increasing the hysteresis of the switching layer 40 and improving the ON/OFF ratio, the first voltage V1 is preferably equal to or less than 0.9 times, more preferably equal to or less than 0.8 times, and even more preferably equal to or less than 0.7 times the first threshold voltage Vth1.

### First Modification Example

A memory device according to a first modification example of the first embodiment includes a memory cell which includes a first conductive layer, a second conductive layer, a switching layer provided between the first conductive layer and the second conductive layer, and a variable resistance layer provided between the switching layer and the second conductive layer, whose electrical resistance changes with the application of a predetermined voltage, and which can have a low resistance state and a high resistance state having a higher electrical resistance than in the low resistance state. The memory device according to the first modification example is different from the memory device according to the first embodiment in that the third conductive layer is not provided. Hereinafter, the description of a part of the content overlapping the first embodiment may be omitted.

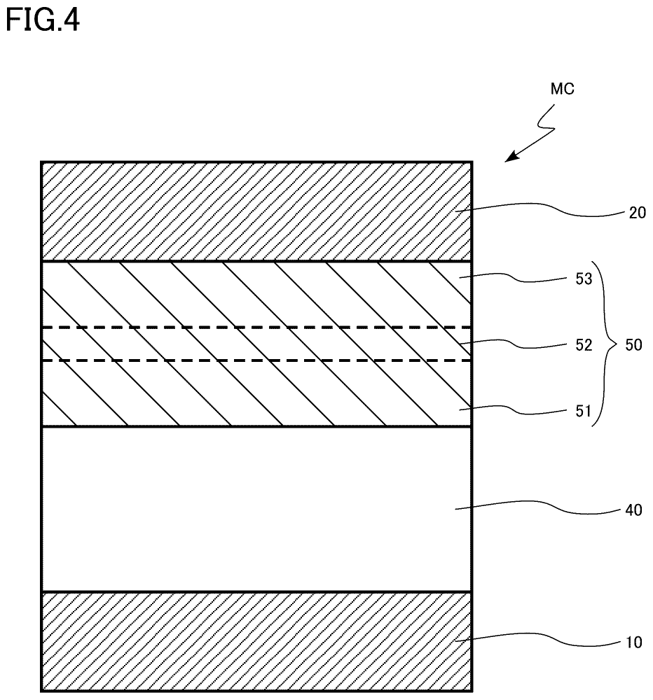

FIG. 4 is a schematic cross-sectional view of a memory cell in the memory device according to the first modification example of the first embodiment. FIG. 4 is a diagram corresponding to FIG. 2 in the first embodiment.

As shown in FIG. 4, the memory cell MC according to the first modification example includes a lower electrode 10, an upper electrode 20, a switching layer 40, and a variable resistance layer 50. The variable resistance layer 50 includes a fixed layer 51, a tunnel layer 52, and a free layer 53.

The lower electrode 10 is an example of the first conductive layer. The upper electrode 20 is an example of the second conductive layer.

The switching layer 40 and the variable resistance layer 50 are in contact with each other.

The switching layer 40 contains at least one first compound selected from a group consisting of molybdenum disulfide, molybdenum diselenide, molybdenum ditelluride, tungsten disulfide, tungsten diselenide, indium selenide, gallium sulfide, gallium selenide, gallium telluride, germanium sulfide, germanium selenide, germanium telluride, silicon sulfide, silicon selenide, silicon telluride, tin sulfide, tin selenide, tin telluride, rhenium disulfide, rhenium diselenide, and rhenium ditelluride.

The lower electrode 10 contains at least one second compound selected from a group consisting of tungsten ditelluride, titanium disulfide, titanium diselenide, tantalum disulfide, tantalum diselenide, niobium disulfide, niobium diselenide, hafnium disulfide, and hafnium diselenide, graphene, or graphite.

According to the memory device according to the first modification example of the first embodiment, similarly to the first embodiment, it is possible to realize a memory device with stable operating characteristics, reduced power consumption, and improved reliability.

### Second Modification Example

A memory device according to a second modification example of the first embodiment is different from the memory device according to the first embodiment in that a memory cell further includes a current suppression layer containing at least one compound selected from a group consisting of aluminum oxide, boron nitride, silicon oxide, aluminum nitride, and silicon nitride. Hereinafter, the description of a part of the content overlapping the first embodiment may be omitted.

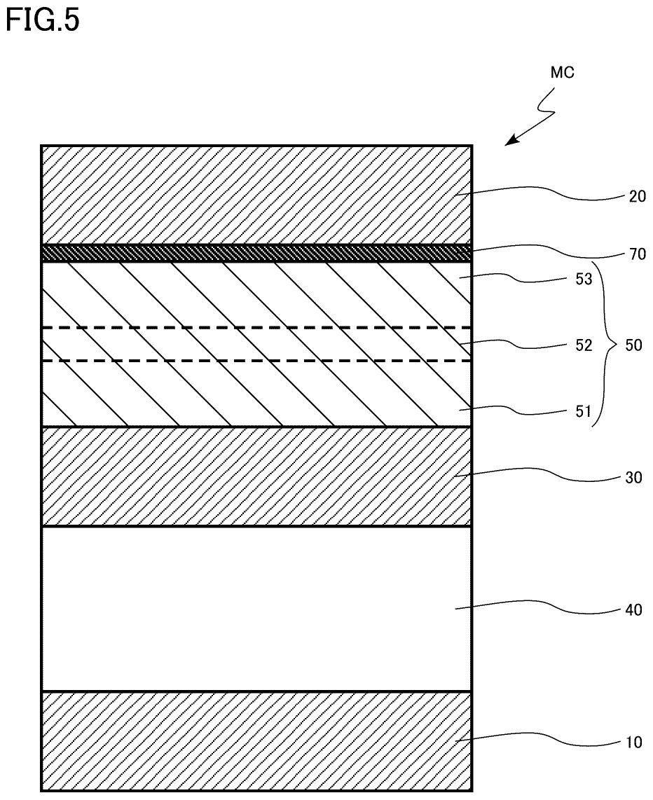

FIG. 5 is a schematic cross-sectional view of a memory cell in the memory device according to the second modification example of the first embodiment. FIG. 5 is a diagram corresponding to FIG. 2 in the first embodiment.

As shown in FIG. 5, the memory cell MC includes a lower electrode 10, an upper electrode 20, an intermediate electrode 30, a switching layer 40, a variable resistance layer 50, and a current suppression layer 70. The variable resistance layer 50 includes a fixed layer 51, a tunnel layer 52, and a free layer 53.

The lower electrode 10 is an example of the first conductive layer. The upper electrode 20 is an example of the second conductive layer. The intermediate electrode 30 is an example of the third conductive layer.

The current suppression layer 70 is provided, for example, between the lower electrode 10 and the upper electrode 20. For example, as shown in FIG. 5, the current suppression layer 70 is provided between the variable resistance layer 50 and the upper electrode 20.

In addition, the position where the current suppression layer 70 is provided is not limited to between the variable resistance layer 50 and the upper electrode 20, and the position where the current suppression layer 70 is provided may be, for example, between the lower electrode 10 and the switching layer 40, between the switching layer 40 and the intermediate electrode 30, or between the intermediate electrode 30 and the variable resistance layer 50. In addition, the current suppression layer 70 may be provided, for example, on the side of the lower electrode 10 opposite to the switching layer 40 or on the side of the upper electrode 20 opposite to the variable resistance layer 50. In addition, the current suppression layer 70 may be provided at a plurality of positions.

The thickness of the current suppression layer 70 in a direction from the lower electrode 10 to the upper electrode 20 is, for example, equal to or more than 0.2 nm and equal to or less than 2 nm.

The current suppression layer 70 contains at least one compound selected from a group consisting of aluminum oxide, boron nitride, silicon oxide, aluminum nitride, and silicon nitride.

According to the memory device according to the second modification example of the first embodiment, similarly to the first embodiment, it is possible to realize a memory device with stable operating characteristics, reduced power consumption, and improved reliability. In addition, in the memory device according to the second modification example of the first embodiment, the current suppression layer 70 suppresses the flow of a large current to the memory cell MC. Therefore, for example, a memory device with high destruction resistance is realized.

As described above, according to the first embodiment and its modification examples, a memory device is realized which has a switching element with excellent characteristics and has stable operating characteristics, reduced power consumption, and improved reliability.

### Second Embodiment

A memory device according to a second embodiment is different from the memory device according to the first embodiment in that the memory device according to the second embodiment is a resistive memory (ReRAM).

Hereinafter, the description of a part of the content overlapping the first embodiment will be omitted.

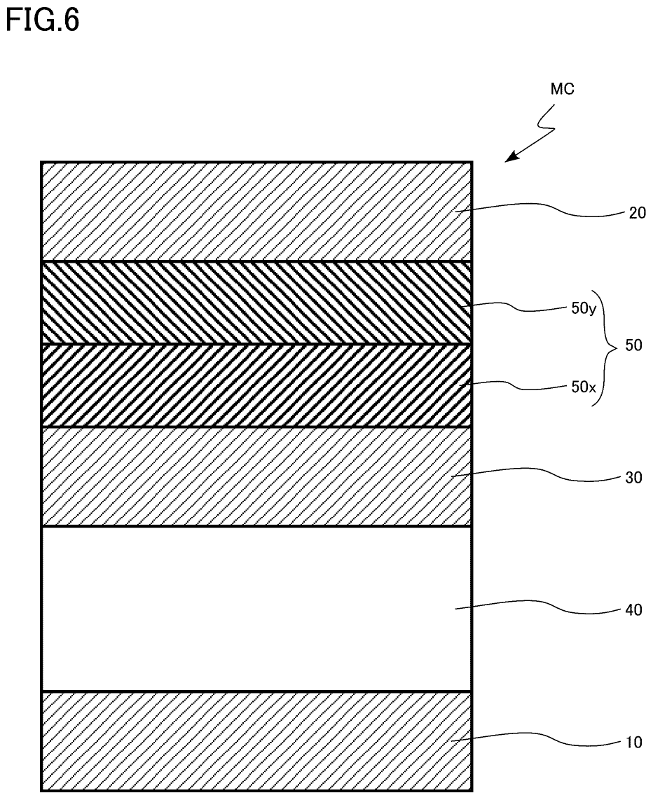

FIG. 6 is a schematic cross-sectional view of a memory cell in the memory device according to the second embodiment. FIG. 6 shows a cross section of one memory cell MC indicated by, for example, a dotted circle in the memory cell array 100 of FIG. 1. FIG. 6 is a diagram corresponding to FIG. 2 in the first embodiment.

As shown in FIG. 6, the memory cell MC includes a lower electrode 10, an upper electrode 20, an intermediate electrode 30, a switching layer 40, and a variable resistance layer 50. The variable resistance layer 50 includes a high resistance layer 50x and a low resistance layer 50y.

The lower electrode 10 is an example of the first conductive layer. The upper electrode 20 is an example of the second conductive layer. The intermediate electrode 30 is an example of the third conductive layer.

The lower electrode 10, the switching layer 40, and the intermediate electrode 30 form a switching element of the memory cell MC. The intermediate electrode 30, the variable resistance layer 50, and the upper electrode 20 form a variable resistance element of the memory cell MC.

The configurations of the switching layer 40, the lower electrode 10, the upper electrode 20, and the intermediate electrode 30 are similar to those in the memory device according to the first embodiment.

The variable resistance layer 50 includes the high resistance layer 50x and the low resistance layer 50y.

The high resistance layer 50x is, for example, a metal oxide. The high resistance layer 50x is, for example, an aluminum oxide, a hafnium oxide, a zirconium oxide, a tantalum oxide, or a niobium oxide.

The low resistance layer 50y is, for example, a metal oxide. The low resistance layer 50y is, for example, a titanium oxide, a niobium oxide, a tantalum oxide, or a tungsten oxide.

The variable resistance layer 50 has a function of storing data by resistance change. The variable resistance layer 50 has, for example, a characteristic that its electrical resistance changes with the application of a predetermined voltage.

By applying a voltage to the variable resistance layer 50, the variable resistance layer 50 changes from a high resistance state to a low resistance state or from a low resistance state to a high resistance state. By applying a voltage to the variable resistance layer 50, oxygen ions move between the high resistance layer 50x and the low resistance layer 50y, so that the amount of oxygen deficiency (the amount of oxygen vacancies) in the low resistance layer 50y changes. The electrical conductivity of the variable resistance layer 50 changes according to the amount of oxygen deficiency in the low resistance layer 50y. The low resistance layer 50y is a so-called vacancy modulated conductive oxide.

For example, the high resistance state is defined as data “1”, and the low resistance state is defined as data “0”. The memory cell MC can store 1-bit data of “0” and “1”.

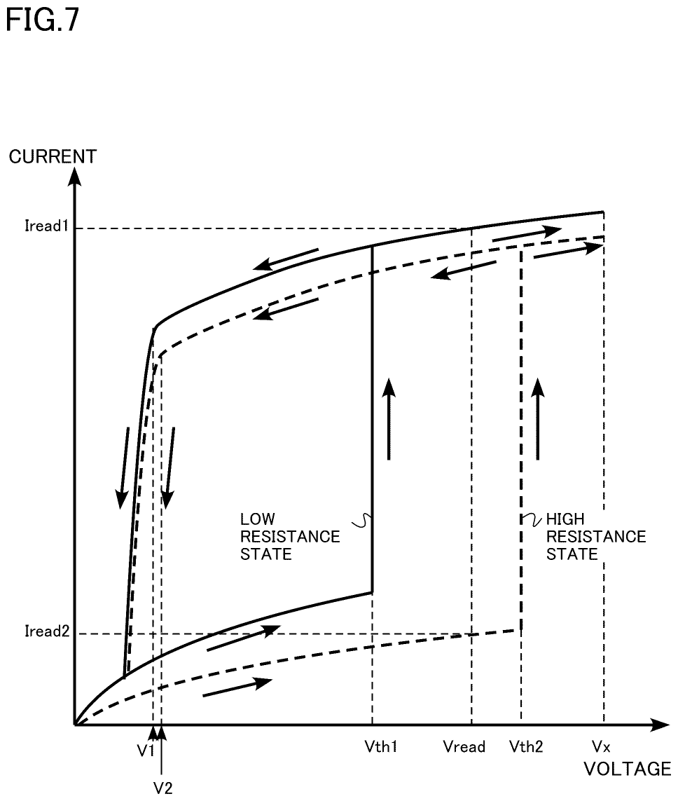

FIG. 7 is an explanatory diagram of the current-voltage characteristic of the memory device according to the second embodiment. FIG. 7 is a diagram corresponding to FIG. 3 in the first embodiment.

In FIG. 7, the solid line shows a current-voltage characteristic when the memory cell MC is in a low resistance state. In addition, in FIG. 7, the dotted line shows a current-voltage characteristic when the memory cell MC is in a high resistance state. In FIG. 7, the arrows along the current-voltage characteristics indicate the sweep direction of the voltage.

First, the current-voltage characteristic when the memory cell MC is in a low resistance state will be described. As the applied voltage increases, a nonlinear current-voltage characteristic that the current increases at a first threshold voltage (Vth1 in FIG. 7) appears.

Thereafter, when the voltage is reduced from a voltage (Vx in FIG. 7) exceeding the first threshold voltage Vth1, the current decreases at a first voltage (V1 in FIG. 7) lower than the first threshold voltage. In other words, when the memory cell MC is in a low resistance state, the current-voltage characteristic of the memory cell MC shows hysteresis. For example, the first voltage V1 is equal to or more than 0.1 times and equal to or less than 0.9 times the first threshold voltage Vth1.

Next, the current-voltage characteristic when the memory cell MC is in a high resistance state will be described. As the applied voltage increases, a nonlinear current-voltage characteristic that the current increases at a second threshold voltage (Vth2 in FIG. 7) appears. Thereafter, when the voltage is reduced from the voltage (Vx in FIG. 7) exceeding the second threshold voltage Vth2, the current decreases at a second voltage (V2 in FIG. 7) lower than the second threshold voltage. In other words, when the memory cell MC is in a high resistance state, the current-voltage characteristic of the memory cell MC shows hysteresis. For example, the second voltage V2 is equal to or more than 0.1 times and equal to or less than 0.9 times the second threshold voltage Vth2.

The second threshold voltage Vth2 is, for example, larger than the first threshold voltage Vth1. In addition, the second voltage V2 is, for example, approximately the same in magnitude as the first voltage V1.

For example, the high resistance state of the variable resistance layer 50 is defined as data “1”, and the low resistance state of the variable resistance layer 50 is defined as data “0”. Since the memory cell MC can maintain different resistance states, it is possible to store 1-bit data of “0” and “1”.

When reading data from the memory cell MC, for example, a voltage between the first threshold voltage Vth1 and the second threshold voltage Vth2 is set as a read voltage Vread. When the memory cell MC is in a low resistance state, a first read current Iread1 flows. In addition, when the memory cell MC is in a high resistance state, a second read current Iread2 flows. The first read current Iread1 is larger than the second read current Iread2. By detecting the magnitude of the read current when the read voltage Vread is applied to the memory cell MC, it is possible to determine the data written in the memory cell MC.

The difference in electrical resistance between the low resistance state and the high resistance state of the variable resistance layer 50 in the resistive memory according to the second embodiment is extremely larger than the difference in electrical resistance between the low resistance state and the high resistance state of the variable resistance layer 50 in the magnetoresistive memory according to the first embodiment. Therefore, the difference between the first read current Iread1 and the second read current Iread2 of the memory cell MC in the resistive memory is extremely larger than the difference between the first read current Iread1 and the second read current Iread2 of the memory cell MC in the magnetoresistive memory.

In addition, in the resistive memory, the current that flows at a voltage less than the first threshold voltage Vth1 in the high resistance state is extremely smaller than the current that flows at a voltage less than the first threshold voltage Vth1 in the low resistance state.

According to the second embodiment, similarly to the first embodiment, it is possible to realize a memory device with stable operating characteristics, reduced power consumption, and improved reliability.

### First Modification Example

A memory device according to a first modification example of the second embodiment is different from the memory device according to the second embodiment in that the third conductive layer is not provided. Hereinafter, the description of a part of the content overlapping the second embodiment may be omitted.

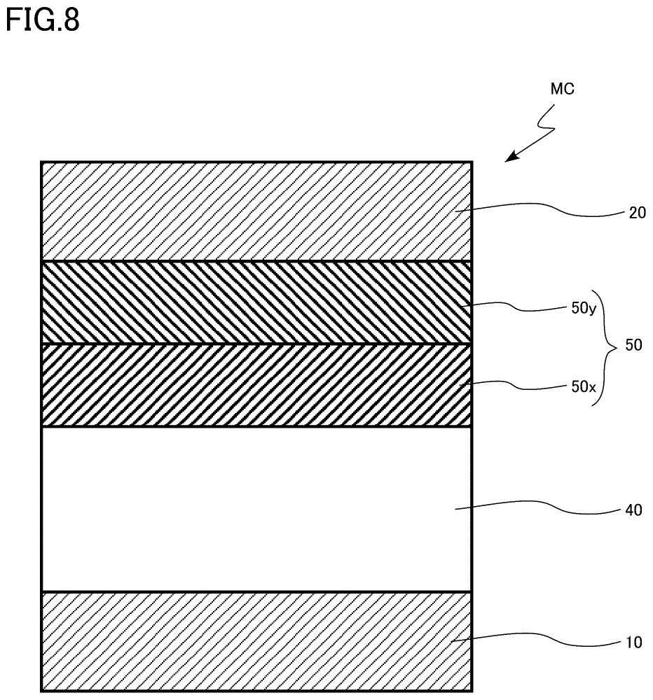

FIG. 8 is a schematic cross-sectional view of a memory cell in the memory device according to the first modification example of the second embodiment. FIG. 8 is a diagram corresponding to FIG. 6 in the second embodiment.

As shown in FIG. 8, the memory cell MC according to the first modification example includes a lower electrode 10, an upper electrode 20, a switching layer 40, and a variable resistance layer 50. The variable resistance layer 50 includes a high resistance layer 50x and a low resistance layer 50y.

The lower electrode 10 is an example of the first conductive layer. The upper electrode 20 is an example of the second conductive layer.

The switching layer 40 and the variable resistance layer 50 are in contact with each other.

The switching layer 40 contains at least one first compound selected from a group consisting of molybdenum disulfide, molybdenum diselenide, molybdenum ditelluride, tungsten disulfide, tungsten diselenide, indium selenide, gallium sulfide, gallium selenide, gallium telluride, germanium sulfide, germanium selenide, germanium telluride, silicon sulfide, silicon selenide, silicon telluride, tin sulfide, tin selenide, tin telluride, rhenium disulfide, rhenium diselenide, and rhenium ditelluride.

The lower electrode 10 contains at least one second compound selected from a group consisting of tungsten ditelluride, titanium disulfide, titanium diselenide, tantalum disulfide, tantalum diselenide, niobium disulfide, niobium diselenide, hafnium disulfide, and hafnium diselenide, graphene, or graphite.

According to the memory device according to the first modification example of the second embodiment, similarly to the second embodiment, it is possible to realize a memory device with stable operating characteristics, reduced power consumption, and improved reliability.

### Second Modification Example

A memory device according to a second modification example of the second embodiment is different from the memory device according to the second embodiment in that a memory cell further includes a current suppression layer containing at least one compound selected from a group consisting of aluminum oxide, boron nitride, silicon oxide, aluminum nitride, and silicon nitride. Hereinafter, the description of a part of the content overlapping the second embodiment may be omitted.

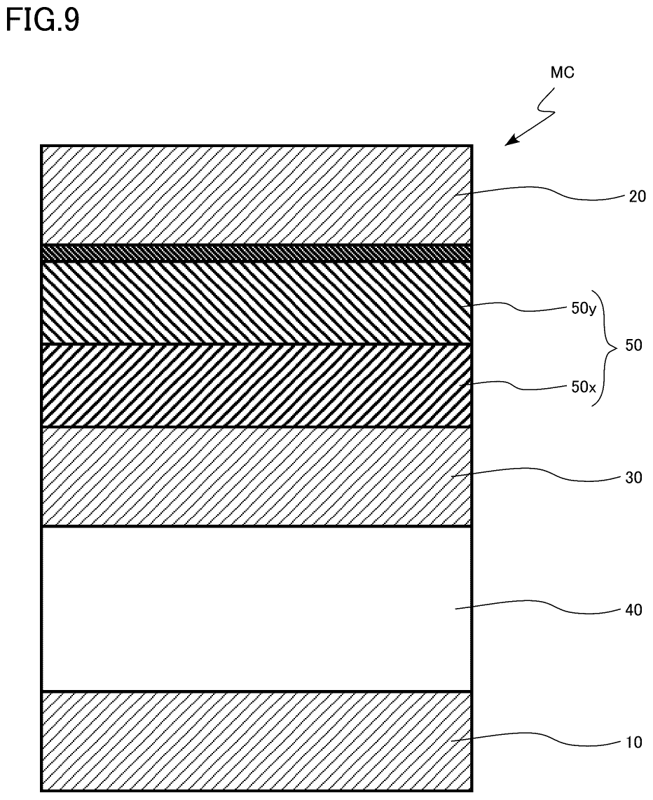

FIG. 9 is a schematic cross-sectional view of a memory cell in the memory device according to the second modification example of the second embodiment. FIG. 9 is a view corresponding to FIG. 6 in the second embodiment.

As shown in FIG. 9, the memory cell MC includes a lower electrode 10, an upper electrode 20, an intermediate electrode 30, a switching layer 40, a variable resistance layer 50, and a current suppression layer 70. The variable resistance layer 50 includes a high resistance layer 50x and a low resistance layer 50y.

The lower electrode 10 is an example of the first conductive layer. The upper electrode 20 is an example of the second conductive layer. The intermediate electrode 30 is an example of the third conductive layer.

The current suppression layer 70 is provided, for example, between the lower electrode 10 and the upper electrode 20. For example, as shown in FIG. 9, the current suppression layer 70 is provided between the variable resistance layer 50 and the upper electrode 20.

In addition, the position where the current suppression layer 70 is provided is not limited to between the variable resistance layer 50 and the upper electrode 20, and the position where the current suppression layer 70 is provided may be, for example, between the lower electrode 10 and the switching layer 40, between the switching layer 40 and the intermediate electrode 30, or between the intermediate electrode 30 and the variable resistance layer 50. In addition, the current suppression layer 70 may be provided, for example, on the side of the lower electrode 10 opposite to the switching layer 40 or on the side of the upper electrode 20 opposite to the variable resistance layer 50. In addition, the current suppression layer 70 may be provided at a plurality of positions.

The thickness of the current suppression layer 70 in a direction from the lower electrode 10 to the upper electrode 20 is, for example, equal to or more than 0.2 nm and equal to or less than 2 nm.

The current suppression layer 70 contains at least one compound selected from a group consisting of aluminum oxide, boron nitride, silicon oxide, aluminum nitride, and silicon nitride.

According to the memory device according to the second modification example of the second embodiment, similarly to the second embodiment, it is possible to realize a memory device with stable operating characteristics, reduced power consumption, and improved reliability. In addition, in the memory device according to the second modification example of the second embodiment, the current suppression layer 70 suppresses the flow of a large current to the memory cell MC. Therefore, for example, a memory device with high destruction resistance is realized.

As described above, according to the second embodiment and its modification examples, a memory device is realized which has a switching element with excellent characteristics and has stable operating characteristics, reduced power consumption, and improved reliability..

### Third Embodiment

A memory device according to a third embodiment is different from the memory device according to the second embodiment in that the memory device according to the third embodiment is a phase change memory (PCM). Hereinafter, the description of a part of the content overlapping the second embodiment will be omitted.

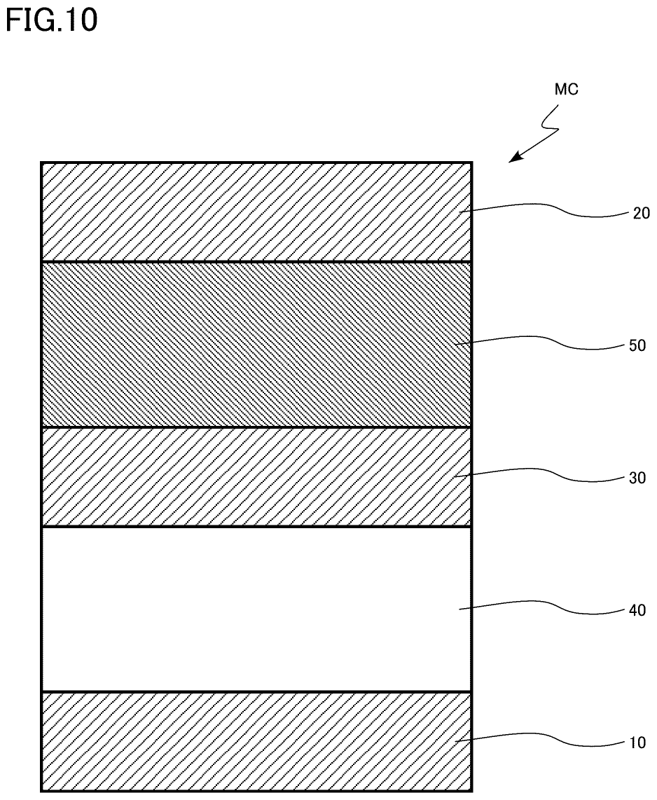

FIG. 10 is a schematic cross-sectional view of a memory cell in the memory device according to the third embodiment. FIG. 10 shows a cross section of one memory cell MC indicated by, for example, a dotted circle in the memory cell array 100 of FIG. 1. FIG. 10 is a diagram corresponding to FIG. 6 in the second embodiment.

As shown in FIG. 10, the memory cell MC includes a lower electrode 10, an upper electrode 20, an intermediate electrode 30, a switching layer 40, and a variable resistance layer 50.

The lower electrode 10 is an example of the first conductive layer. The upper electrode 20 is an example of the second conductive layer. The intermediate electrode 30 is an example of the third conductive layer.

The lower electrode 10, the switching layer 40, and the intermediate electrode 30 form a switching element of the memory cell MC. The intermediate electrode 30, the variable resistance layer 50, and the upper electrode 20 form a variable resistance element of the memory cell MC.

The configurations of the switching layer 40, the lower electrode 10, the upper electrode 20, and the intermediate electrode 30 are similar to those in the memory device according to the second embodiment.

The variable resistance layer 50 is, for example, a chalcogenide. The variable resistance layer 50 contains, for example, germanium (Ge), antimony (Sb), and tellurium (Te).

The variable resistance layer 50 has a function of storing data by resistance change. The variable resistance layer 50 has, for example, a characteristic that its electrical resistance changes with the application of a predetermined voltage.

By applying a voltage to the variable resistance layer 50, the variable resistance layer 50 changes from a high resistance state to a low resistance state, or from a low resistance state to a high resistance state. Due to the application of a voltage to the variable resistance layer 50, the variable resistance layer 50 transitions between a crystalline state and an amorphous state. For example, the crystalline state is the low resistance state of the memory cell MC, and the amorphous state is the high resistance state of the memory cell MC.

For example, the high resistance state is defined as data “1”, and the low resistance state is defined as data “0”. The memory cell MC can store 1-bit data of “0” and “1”.

The current-voltage characteristic of the memory device according to the third embodiment is similar to the current-voltage characteristic of the memory device according to the second embodiment shown in FIG. 7, for example.

As described above, according to the third embodiment, a memory device is realized which has a switching element with excellent characteristics and has stable operating characteristics, reduced power consumption, and improved reliability.

### Fourth Embodiment

A memory device according to a fourth embodiment includes a memory cell which includes a first conductive layer, a second conductive layer, and a memory layer provided between the first conductive layer and the second conductive layer, whose electrical resistance changes with the application of a predetermined voltage, and which can have a low resistance state and a high resistance state having a higher electrical resistance than in the low resistance state. The memory layer contains at least one first compound selected from a group consisting of molybdenum disulfide, molybdenum diselenide, molybdenum ditelluride, tungsten disulfide, tungsten diselenide, indium selenide, gallium sulfide, gallium selenide, gallium telluride, germanium sulfide, germanium selenide, germanium telluride, silicon sulfide, silicon selenide, silicon telluride, tin sulfide, tin selenide, tin telluride, rhenium disulfide, rhenium diselenide, and rhenium ditelluride. At least one of the first conductive layer and the second conductive layer contains at least one second compound selected from a group consisting of tungsten ditelluride, titanium disulfide, titanium diselenide, tantalum disulfide, tantalum diselenide, niobium disulfide, niobium diselenide, hafnium disulfide, and hafnium diselenide, graphene, or graphite. When the memory cell is in a low resistance state, if a voltage is applied between the first conductive layer and the second conductive layer, a nonlinear current-voltage characteristic that the current increases at a first threshold voltage appears as the absolute value of the voltage increases, and a current-voltage characteristic that the current decreases at a first voltage having an absolute value smaller than that of the first threshold voltage appears as the absolute value of the voltage decreases from a voltage exceeding the first threshold voltage.

In addition, the memory device according to the fourth embodiment further includes a plurality of first wirings and a plurality of second wirings crossing the plurality of first wirings. Then, the memory cell is provided in a region where one of the plurality of first wirings crosses one of the plurality of second wirings.

The memory device according to the fourth embodiment is different from the memory device according to the first embodiment in that the memory cell does not include a third conductive layer and a variable resistance layer and includes a structure similar to the switching layer in the first embodiment as a memory layer. Hereinafter, the description of a part of the content overlapping the first embodiment will be omitted.

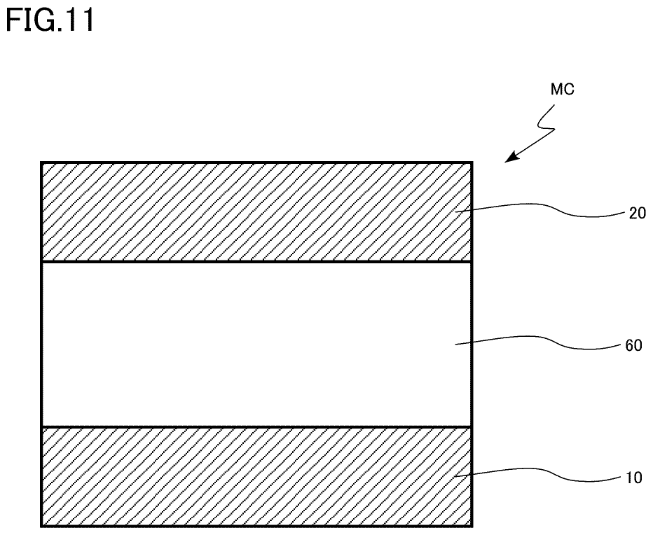

FIG. 11 is a schematic cross-sectional view of a memory cell in the memory device according to the fourth embodiment. FIG. 11 shows a cross section of one memory cell MC indicated by, for example, a dotted circle in the memory cell array 100 of FIG. 1.

As shown in FIG. 11, the memory cell MC includes a lower electrode 10, an upper electrode 20, and a memory layer 60.

The lower electrode 10 is an example of the first conductive layer. The upper electrode 20 is an example of the second conductive layer.

The lower electrode 10, the memory layer 60, and the upper electrode 20 form a memory element of the memory cell MC. The memory element of the memory cell MC has a switching function and an information storage function.

The memory layer 60 has a configuration similar to that of the switching layer 40 in the first embodiment.

The configurations of the lower electrode 10 and the upper electrode 20 are similar to the configurations of the lower electrode 10 and the intermediate electrode 30 in the memory device according to the first embodiment.

The memory layer 60 has a nonlinear current-voltage characteristic in which a current increases abruptly at a specific threshold voltage. In addition, the memory layer 60 has a characteristic that the threshold voltage changes with the application of a predetermined voltage. The memory layer 60 has a characteristic that its electrical resistance changes with the application of a predetermined voltage.

The memory layer 60 has a function of suppressing an increase in leakage current flowing through unselected cells. In addition, the memory layer 60 has a function of storing data by resistance change. The memory layer 60 alone realizes both the function of the switching layer 40 and the function of the variable resistance layer 50 in the first embodiment.

At least one of the lower electrode 10 and the intermediate electrode 30 contains at least one second compound selected from a group consisting of tungsten ditelluride, titanium disulfide, titanium diselenide, tantalum disulfide, tantalum diselenide, niobium disulfide, niobium diselenide, hafnium disulfide, and hafnium diselenide, graphene, or graphite.

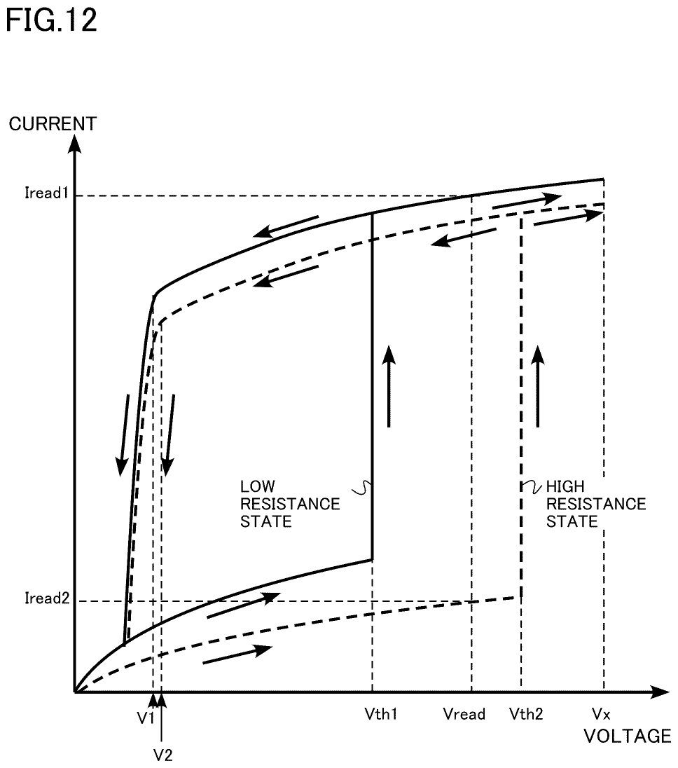

FIG. 12 is an explanatory diagram of the current-voltage characteristic of the memory device according to the fourth embodiment. FIG. 12 is a diagram corresponding to FIG. 7 in the second embodiment.

In FIG. 12, the solid line shows a current-voltage characteristic when the memory cell MC is in a low resistance state. In addition, in FIG. 12, the dotted line shows a current-voltage characteristic when the memory cell MC is in a high resistance state. In FIG. 12, the arrows along the current-voltage characteristics indicate the sweep direction of the voltage.

First, the current-voltage characteristic when the memory cell MC is in a low resistance state will be described. As the applied voltage increases, a nonlinear current-voltage characteristic that the current increases at a first threshold voltage (Vth1 in FIG. 12) appears. Thereafter, when the voltage is reduced from a voltage (Vx in FIG. 12) exceeding the first threshold voltage Vth1, the current decreases at a first voltage (V1 in FIG. 12) lower than the first threshold voltage. In other words, when the memory cell MC is in a low resistance state, the current-voltage characteristic of the memory cell MC shows hysteresis. For example, the first voltage V1 is equal to or more than 0.1 times and equal to or less than 0.9 times the first threshold voltage Vth1.

Next, the current-voltage characteristic when the memory cell MC is in a high resistance state will be described. As the applied voltage increases, a nonlinear current-voltage characteristic that the current increases at a second threshold voltage (Vth2 in FIG. 12) appears. Thereafter, when the voltage is reduced from the voltage (Vx in FIG. 12) exceeding the second threshold voltage Vth2, the current decreases at a second voltage (V2 in FIG. 12) lower than the second threshold voltage Vth2. In other words, when the memory cell MC is in a high resistance state, the current-voltage characteristic of the memory cell MC shows hysteresis. For example, the second voltage V2 is equal to or more than 0.1 times and equal to or less than 0.9 times the second threshold voltage Vth2.

The second threshold voltage Vth2 is, for example, larger than the first threshold voltage Vth1. In addition, the second voltage V2 is, for example, approximately the same in magnitude as the first voltage V1.

For example, the high resistance state of the memory cell MC is defined as data “1”, and the low resistance state is defined as data “0”. Since the memory cell MC can maintain different resistance states, it is possible to store 1-bit data of “0” and “1”.

When reading data from the memory cell MC, for example, a voltage between the first threshold voltage Vth1 and the second threshold voltage Vth2 is set as a read voltage Vread. When the memory cell MC is in a low resistance state, a first read current Iread1 flows. In addition, when the memory cell MC is in a high resistance state, a second read current Iread2 flows. The first read current Iread1 is larger than the second read current Iread2. By detecting the magnitude of the read current when the read voltage Vread is applied to the memory cell MC, it is possible to determine the data written in the memory cell MC.

According to the fourth embodiment, similarly to the first and second embodiments, it is possible to realize a memory device with stable operating characteristics, reduced power consumption, and improved reliability.

### Modification Example

A memory device according to a modification example of the fourth embodiment is different from the memory device according to the fourth embodiment in that the memory cell further includes a current suppression layer containing at least one compound selected from a group consisting of aluminum oxide, boron nitride, silicon oxide, aluminum nitride, and silicon nitride. Hereinafter, the description of a part of the content overlapping the fourth embodiment may be omitted.

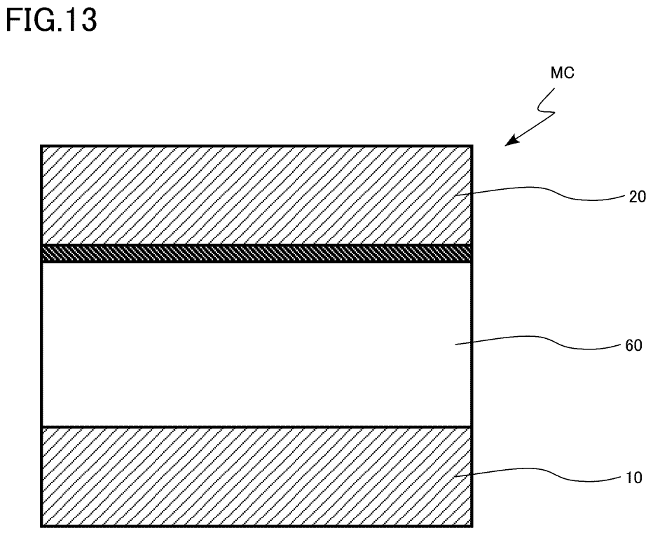

FIG. 13 is a schematic cross-sectional view of a memory cell in the memory device according to the modification example of the fourth embodiment. FIG. 13 is a diagram corresponding to FIG. 11 in the fourth embodiment.

As shown in FIG. 13, the memory cell MC includes a lower electrode 10, an upper electrode 20, a memory layer 60, and a current suppression layer 70.

The lower electrode 10 is an example of the first conductive layer. The upper electrode 20 is an example of the second conductive layer.

The current suppression layer 70 is provided, for example, between the lower electrode 10 and the upper electrode 20. For example, as shown in FIG. 13, the current suppression layer 70 is provided between the memory layer 60 and the upper electrode 20.

In addition, the position where the current suppression layer 70 is provided is not limited to between the memory layer 60 and the upper electrode 20. The position where the current suppression layer 70 is provided may be, for example, between the lower electrode 10 and the memory layer 60. In addition, the current suppression layer 70 may be provided, for example, on the side of the lower electrode 10 opposite to the memory layer 60 or on the side of the upper electrode 20 opposite to the memory layer 60. In addition, the current suppression layer 70 may be provided at a plurality of positions.

The thickness of the current suppression layer 70 in a direction from the lower electrode 10 to the upper electrode 20 is, for example, equal to or more than 0.2 nm and equal to or less than 2 nm.

The current suppression layer 70 contains at least one compound selected from a group consisting of aluminum oxide, boron nitride, silicon oxide, aluminum nitride, and silicon nitride.

According to the memory device according to the modification example of the fourth embodiment, the current suppression layer 70 suppresses the flow of a large current to the memory cell MC. Therefore, for example, a memory device with high destruction resistance is realized.

As described above, according to the fourth embodiment and its modification example, a memory device is realized which has a switching element with excellent characteristics and has stable operating characteristics, reduced power consumption, and improved reliability.

Although the magnetoresistive memory has been described as an example of the two-terminal memory device in the first embodiment, the resistive memory has been described as an example of the two-terminal memory device in the second embodiment, and the phase change memory has been described as an example of the two-terminal memory device in the third embodiment, embodiments can be applied to other two-terminal memory devices. For example, embodiments can be applied to a ferroelectric random access memory (FeRAM).

While certain embodiments have been described, these embodiments have been presented by way of example only, and are not intended to limit the scope of the inventions. Indeed, the memory device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A memory device, comprising:
a memory cell including a first conductive layer, a second conductive layer, a third conductive layer provided between the first conductive layer and the second conductive layer, a switching layer provided between the first conductive layer and the third conductive layer, and a variable resistance layer provided between the third conductive layer and the second conductive layer, the memory cell having an electrical resistance changing with application of a predetermined voltage and having a low resistance state and a high resistance state having a higher electrical resistance than in the low resistance state,
wherein the switching layer contains at least one first compound selected from a group consisting of molybdenum disulfide, molybdenum diselenide, molybdenum ditelluride, tungsten disulfide, tungsten diselenide, indium selenide, gallium sulfide, gallium selenide, gallium telluride, germanium sulfide, germanium selenide, germanium telluride, silicon sulfide, silicon selenide, silicon telluride, tin sulfide, tin selenide, tin telluride, rhenium disulfide, rhenium diselenide, and rhenium ditelluride,
at least one of the first conductive layer and the third conductive layer contains at least one second compound selected from a group consisting of tungsten ditelluride, titanium disulfide, titanium diselenide, tantalum disulfide, tantalum diselenide, niobium disulfide, niobium diselenide, hafnium disulfide, and hafnium diselenide, graphene, or graphite, and
when the memory cell is in the low resistance state, if a voltage is applied between the first conductive layer and the second conductive layer, a nonlinear current-voltage characteristic that a current increases at a first threshold voltage appears as an absolute value of the voltage increases, and a current-voltage characteristic that a current decreases at a first voltage having an absolute value smaller than that of the first threshold voltage appears as the absolute value of the voltage decreases from a voltage exceeding the first threshold voltage.

2. The memory device according to claim 1,
wherein the switching layer contains crystals of a space group P63/mmc, crystals of a space group Pnma62, or crystals of a space group P-1.

3. The memory device according to claim 1,
wherein a thickness of the switching layer in a direction from the first conductive layer to the second conductive layer is equal to or more than 0.5 nm and equal to or less than 50 nm.

4. The memory device according to claim 1,
wherein the variable resistance layer has an electrical resistance changing with application of a predetermined voltage, and
the switching layer has a nonlinear current-voltage characteristic that a current increases at a specific threshold voltage.

5. The memory device according to claim 1,
wherein the variable resistance layer includes a magnetic tunnel junction.

6. The memory device according to claim 1,
wherein the memory cell further includes a current suppression layer containing at least one compound selected from a group consisting of aluminum oxide, boron nitride, silicon oxide, aluminum nitride, and silicon nitride.

7. The memory device according to claim 1, further comprising:
a plurality of first wirings; and
a plurality of second wirings crossing the plurality of first wirings,
wherein the memory cell is provided in a region where one of the plurality of first wirings and one of the plurality of second wirings cross each other.

8. A memory device, comprising:
a memory cell including a first conductive layer, a second conductive layer, a switching layer provided between the first conductive layer and the second conductive layer, and a variable resistance layer provided between the switching layer and the second conductive layer, the memory cell having an electrical resistance changing with application of a predetermined voltage and having a low resistance state and a high resistance state having a higher electrical resistance than in the low resistance state,
wherein the switching layer contains at least one first compound selected from a group consisting of molybdenum disulfide, molybdenum diselenide, molybdenum ditelluride, tungsten disulfide, tungsten diselenide, indium selenide, gallium sulfide, gallium selenide, gallium telluride, germanium sulfide, germanium selenide, germanium telluride, silicon sulfide, silicon selenide, silicon telluride, tin sulfide, tin selenide, tin telluride, rhenium disulfide, rhenium diselenide, and rhenium ditelluride,
the first conductive layer contains at least one second compound selected from a group consisting of tungsten ditelluride, titanium disulfide, titanium diselenide, tantalum disulfide, tantalum diselenide, niobium disulfide, niobium diselenide, hafnium disulfide, and hafnium diselenide, graphene, or graphite, and
when the memory cell is in the low resistance state, if a voltage is applied between the first conductive layer and the second conductive layer, a nonlinear current-voltage characteristic that a current increases at a first threshold voltage appears as an absolute value of the voltage increases, and a current-voltage characteristic that a current decreases at a first voltage having an absolute value smaller than that of the first threshold voltage appears as the absolute value of the voltage decreases from a voltage exceeding the first threshold voltage.

9. The memory device according to claim 8,
wherein the switching layer contains crystals of a space group P63/mmc, crystals of a space group Pnma62, or crystals of a space group P-1.

10. The memory device according to claim 8,
wherein a thickness of the switching layer in a direction from the first conductive layer to the second conductive layer is equal to or more than 0.5 nm and equal to or less than 50 nm.

11. The memory device according to claim 8,
wherein the variable resistance layer has an electrical resistance changing with application of a predetermined voltage, and
the switching layer has a nonlinear current-voltage characteristic that a current increases at a specific threshold voltage.

12. The memory device according to claim 8,
wherein the variable resistance layer includes a magnetic tunnel junction.

13. The memory device according to claim 8,
wherein the memory cell further includes a current suppression layer containing at least one compound selected from a group consisting of aluminum oxide, boron nitride, silicon oxide, aluminum nitride, and silicon nitride.

14. The memory device according to claim 8, further comprising:
a plurality of first wirings; and
a plurality of second wirings crossing the plurality of first wirings,
wherein the memory cell is provided in a region where one of the plurality of first wirings and one of the plurality of second wirings cross each other.

15. A memory device, comprising:
a memory cell including a first conductive layer, a second conductive layer, and a memory layer provided between the first conductive layer and the second conductive layer and having a characteristic that a threshold voltage changes, a current increasing at the threshold voltage by application of a predetermined voltage, and the memory cell having a low resistance state and a high resistance state having a higher electrical resistance than in the low resistance state,
wherein the memory layer contains at least one first compound selected from a group consisting of molybdenum disulfide, molybdenum diselenide, molybdenum ditelluride, tungsten disulfide, tungsten diselenide, indium selenide, gallium sulfide, gallium selenide, gallium telluride, germanium sulfide, germanium selenide, germanium telluride, silicon sulfide, silicon selenide, silicon telluride, tin sulfide, tin selenide, tin telluride, rhenium disulfide, rhenium diselenide, and rhenium ditelluride,
at least one of the first conductive layer and the second conductive layer contains at least one second compound selected from a group consisting of tungsten ditelluride, titanium disulfide, titanium diselenide, tantalum disulfide, tantalum diselenide, niobium disulfide, niobium diselenide, hafnium disulfide, and hafnium diselenide, graphene, or graphite, and
when the memory cell is in the low resistance state, if a voltage is applied between the first conductive layer and the second conductive layer, a nonlinear current-voltage characteristic that a current increases at a first threshold voltage appears as an absolute value of the voltage increases, and a current-voltage characteristic that a current decreases at a first voltage having an absolute value smaller than that of the first threshold voltage appears as the absolute value of the voltage decreases from a voltage exceeding the first threshold voltage.

16. The memory device according to claim 15,
wherein the memory layer contains crystals of a space group P63/mmc, crystals of a space group Pnma62, or crystals of a space group P-1.

17. The memory device according to claim 15,
wherein a thickness of the memory layer in a direction from the first conductive layer to the second conductive layer is equal to or more than 0.5 nm and equal to or less than 50 nm.

18. The memory device according to claim 15,
wherein the memory cell further includes a current suppression layer containing at least one compound selected from a group consisting of aluminum oxide, boron nitride, silicon oxide, aluminum nitride, and silicon nitride.

19. The memory device according to claim 15, further comprising:
a plurality of first wirings; and
a plurality of second wirings crossing the plurality of first wirings,
wherein the memory cell is provided in a region where one of the plurality of first wirings and one of the plurality of second wirings cross each other.
